(19) United States
(12) Patent Application Publication
(10) Pub. No.: US 2024/0210906 A1
(43) Pub. Date: Jun. 27, 2024

(54) SUBSTRATE PROCESSING APPARATUS WITH CAPABILITIES OF AUTOMATIC DEVICE CONFIGURATION AND A METHOD THEREOF

(71) Applicant: ASM IP Holding B.V., Almere (NL)

(72) Inventors: Tsutomu Makino, Tokyo (JP); Trung Ngo Minh, Sagamihara-shi (JP)

(21) Appl. No.: 18/392,538

(22) Filed: Dec. 21, 2023

Related U.S. Application Data
(60) Provisional application No. 63/476,980, filed on Dec. 23, 2022.

(51) Int. Cl. G05B 19/042

(52) U.S. Cl. CPC G05B 19/0423; G05B 2219/2228

(57) ABSTRACT

A semiconductor processing apparatus is presented. The apparatus comprising a plurality of process modules, each of them configured to process wafers, and wherein each of the plurality of process modules comprising a plurality of slaves configured to receive and process wafers and a control unit comprising a processor and a memory and the control unit communicably connected to the plurality of slaves in series or in parallel, the control unit configured to configure and control the plurality of slaves, wherein the processor is configured to read at least one configuration data file from the memory, generate at least one configuration file of the status of the plurality of slaves based on the at least one configuration data file, enable/disable the plurality of slaves according to the generated at least one configuration file, and load applications to control the plurality of slaves.

### CROSS-REFERENCE TO RELATED APPLICATION(S)

This Application claims the benefit of U.S. Provisional Application 63/476,980 filed on Dec. 23, 2022, the entire contents of which are incorporated herein by reference.

### FIELD OF INVENTION

The present disclosure relates to a substrate processing apparatus for processing a substrate, particularly to an apparatus with automatic configuration capabilities, and a method of automatic configuration in a substrate processing apparatus.

### BACKGROUND OF THE DISCLOSURE

A substrate processing apparatus comprises a plurality of devices like reaction chambers, valves, and wafer handling units and other units.

In a substrate processing apparatus, reaction chambers may be collectively gathered for operation and this collection of reaction chambers may be called a process module (PM). Usually, the PM may have 2 or 4 reaction chambers.

FIG. 1 illustrates an example of a substrate processing apparatus 100. The apparatus 100 includes 4 PMs (PM1 110, PM2 120, PM3 130, and PM4 140). Each of the PMs has 4 reaction chambers, i.e., PM1 110 has reaction chambers (111, 112, 113, 114) and PM2 120 has reaction chambers (121, 122, 123, 124) and PM3 130 has reaction chambers (131, 132, 133, 134) and PM4 140 has reaction chambers (141, 142, 143, 144), respectively. Other than the PMs, the apparatus 100 also comprises a wafer handling chamber 103, and a plurality of wafer handling units 101, 102.

As shown in FIG. 1, each PM has its own reaction chambers and each chamber can be active (enabled) or inactive (disabled) due to processing environment or any other causes. The chambers in a PM may be called slaves and every PM should configure the status of its slaves before a process starts. There may be many different types of devices that can be defined as slaves.

For PM1 110, the configuration file (in part) 151 is shown. In FIG. 1, PM1's configuration 151 shows that only slave 1 (111) and slave 2 (112) is active.

So far, the configuration files 151, 152, 153, 154 for each PMs 110, 120, 130, 140 are updated manually when configuring the PMs in an apparatus 100. This manual configuration is time-consuming and inefficient due to shutting down the operation of an apparatus and human error during editing of the configuration.

Therefore, this disclosure intends to provide a more flexible and reliable configuration method and apparatus with automatic configuration.

### SUMMARY OF THE DISCLOSURE

This summary is provided to introduce a selection of concepts in a simplified form. These concepts are described in further detail in the detailed description of example embodiments of the disclosure below.

This summary is not intended to identify key features or essential features of the claimed subject matter, nor is it intended to be used to limit the scope of the claimed subject matter.

In accordance with one embodiment there may be provided, a semiconductor processing apparatus, comprising: a plurality of process modules, each of them configured to process wafers; and each of the plurality of process modules comprises: a plurality of slaves configured to receive and process wafers; and a control unit comprising a processor and a memory, the control unit communicably connected to the plurality of slaves in series or in parallel and the control unit configured to configure and control the plurality of slaves; wherein the processor is configured to read at least one configuration data file from the memory, generate at least one configuration file of the status of the plurality of slaves based on the at least one configuration data file, enable/disable the plurality of slaves according to the generated at least one configuration file, and load applications to control the plurality of slaves.

In at least one aspect, one of the at least one configuration data file is configured to contain information of the status of the plurality of slaves.

In at least one aspect, the processor is further configured to generate a topology of the plurality of slaves.

In at least one aspect, the control unit further comprising a first control unit and a second control unit; and wherein the second control unit communicably connected to the first control unit and communicably connected to the plurality of slaves in series or in parallel.

In at least one aspect, the first control unit comprising a first processor and a first memory, and wherein the first processor is configured to read at least one configuration data file from the first memory, generate at least one configuration file of the status of the plurality of slaves based on the at least one configuration data file, enable/disable the plurality of slaves according to the generated at least one configuration file, and load applications in the second processor to control the plurality of slaves.

In accordance with one embodiment there may be provided, a semiconductor processing apparatus, comprising: a plurality of process modules, each of them configured to process wafers; and each of the plurality of process modules comprising: a plurality of slaves configured to receive and process wafers; and a control unit comprising a processor and a memory, and the control unit communicably connected to the plurality of slaves in series or in parallel, the control unit configured to configure and control the plurality of slaves, wherein the processor is configured to read configuration information from the memory, generate a pointer table according to the configuration information and a load table based on the plurality of slaves connected to the control unit in the memory, and connect pointers from the link table to the pointer table according to the configuration information.

In at least one aspect, the control unit comprising a first control unit and a second control unit; and the second control unit communicably connected to the first control unit and communicably connected to the plurality of slaves in series or in parallel.

In at least one aspect, the control unit further comprising a first control unit and a second control unit, and the second control unit comprising a second processor and a second memory.

In at least one aspect, the second processor is configured to receive a configuration information from the first control 1nit, generate a pointer table according to the configuration information and a load table based on the plurality of slaves connected to the second control unit in the second memory, and connect pointers from the link table to the pointer table according to the configuration information.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates a prior art showing the overall system structure of substrate processing apparatus, the process modules in the apparatus and the slaves in each of the process modules.

FIG. 2(a) illustrates an example of configuration raw file with 2 slaves (slave 1 and slave 2) enabled according to an embodiment of the present disclosure.

FIG. 2(b) illustrates an example of configuration matrix with 2 enabled slaves (slave 1 and slave 2) derived from the configuration raw file of FIG. 2(a) according to an embodiment of the present disclosure.

FIG. 2(c) illustrates an example of configuration raw file with 4 slaves (slave 1, slave 2, slave 3, and slave 4) enabled according to an embodiment of the present disclosure.

FIG. 2(d) illustrates an example of configuration matrix with 4 enabled slaves (slave 1, slave 2, slave 3, and slave 4) derived from the configuration raw file of FIG. 2(c) according to an embodiment of the present disclosure.

FIG. 3(a) illustrates an example of a control unit 300 comprising 2 independent control units 310, 320 used as a process module controller according to an embodiment of the present disclosure.

FIG. 3(b) illustrates an example of a single control unit 350 used as a process module controller according to an embodiment of the present disclosure.

FIG. 4(a) illustrates an example of how configuration is done in the control unit 400's 2 independent control units 410, 420 according to an embodiment of the present disclosure.

FIG. 4(b) illustrates an example of how configuration is done in the control unit 450 according to another embodiment of the present disclosure.

FIG. 5 illustrates a diagram example on how the present disclosure's method generates a configuration file 530 from configuration matrix 510, configuration raw file 520 and additional files 525 (if needed) according to an embodiment of the present disclosure.

FIG. 6 illustrates a flowchart of auto configuration with the present disclosure's method according to an embodiment of the present disclosure.

FIG. 7 illustrates an example of system overview method of automatic configuration of substrate processing apparatus according to an embodiment of the present disclosure.

FIG. 8(a) illustrates a prior art about how a link table is used for configuration.

FIG. 8(b) illustrates a method flowchart on how a link table is connected with a pointer table for configuration with one-control unit structure according to another embodiment of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail.

Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

The present disclosure will be explained with related figures.

But currently, changes need to be manually edited and configured when they occur and there is no automatic configuration that takes place for substrate processing apparatus.

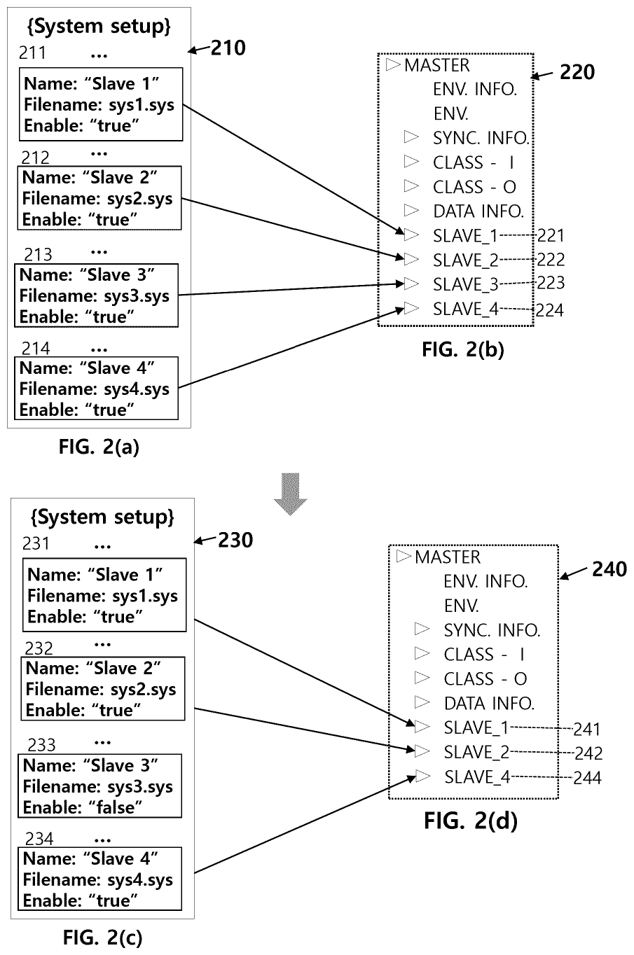

FIG. 2(a) and FIG. 2(c) show examples of configuration raw files and FIG. 2(b) and FIG. 2(d) show corresponding examples of configuration matrix. The explanation below may be simplified for explanation and there may be many different types of slaves. For simple explanation, in this disclosure slave means a processing chamber.

In the configuration raw file 210 of FIG. 2(a), the information needed to configure a PM is displayed. In this example, slaves 1˜4 (211, 212, 213, 214) are all active (enabled) resulting in a configuration matrix 220 having four slaves for configuration 221, 222, 223, 224.

The configuration raw file 210 may contain all the needed information for the configuration of a PM such that what slaves are active (enabled) and what slaves are not active (disabled). The configuration raw file 210 also may contain the additional file names for detailed information provided for PM configuration. (“Filename: sys1.sys”)

The configuration matrix 220 is a configuration used by the process module controller (PMC) for configuring the PM.

In this example, the configuration matrix 220 has 4 slaves (221, 222, 223, 224) for its functioning and these result from the corresponding configuration raw file 210.

Suppose the PM's setup has changed into a new one such that slave 3 (233) is temporarily unavailable or unnecessary. In this case, the configuration raw file 230 would contain all the same except slave 3 (233) resulting in a new configuration matrix 240 with no ‘slave 3’ in the slave lists. Since PMC is reading the configuration matrix 220, 240 to configure its PM, configuration matrix 220 and configuration matrix 240 will get a completely different PM configuration.

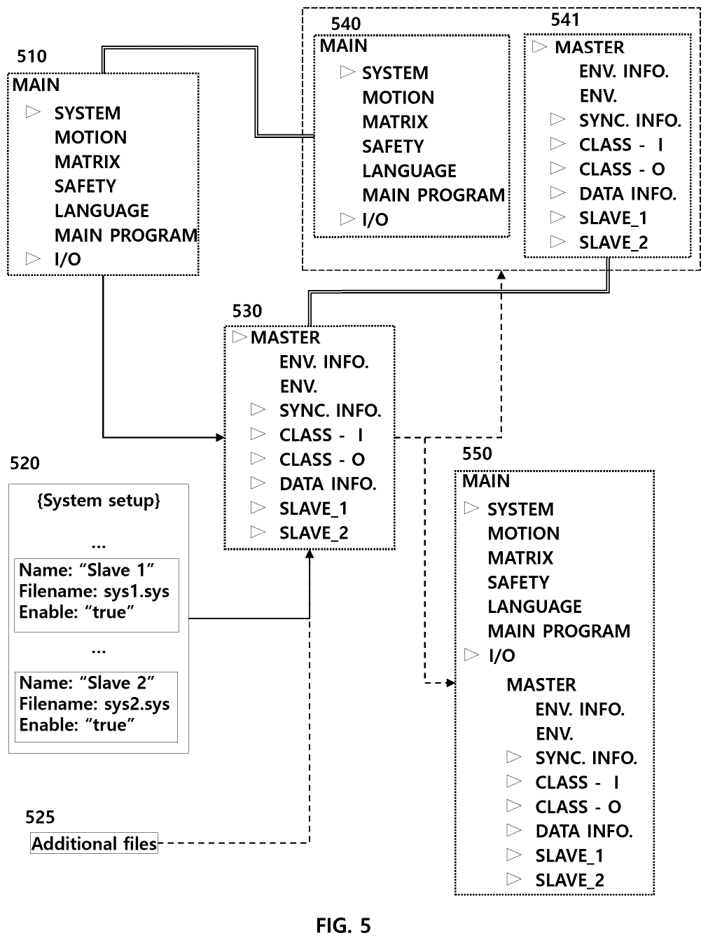

In FIG. 5, an overview of files created from the configuration method is presented.

At first, an empty configuration matrix 510 and a configuration raw file 520 may be prepared along with additional files 525 needed for detailed configuration. When configuration starts, a configuration info. file 530 is generated based on the related files 510, 520, 525.

After generation of the configuration info. file 530, there could be 2 possible statuses for the files. First, a configuration matrix 540 and a configuration info. file 541 may co-exist at the same time for a PMC to read the configuration info. file 541 for configuring the PM. Second, the configuration matrix 510 may be transformed with the contents of the configuration info. file 530 into a final configuration matrix 550. The PMC may still read the final configuration matrix 550 for configuring the PM.

It should be noted that configuration info. file 530 and configuration info. file 541 are identical and also the configuration matrix 510 and configuration matrix 540 are also identical.

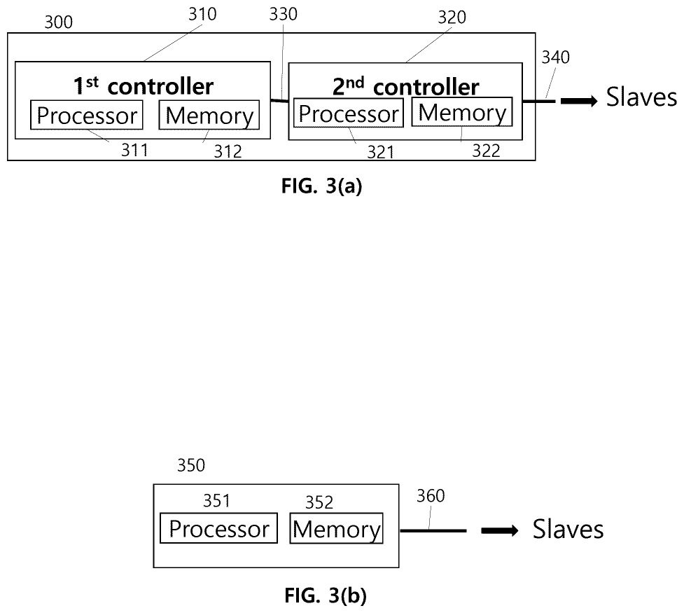

FIG. 3(a) illustrates an example of a control unit 300 comprising a first controller 310 and a second controller 320 used as a process module controller.

The first controller 310 and the second controller 320 may comprise independent controllers. First controller 310 may comprise a processor 311 and a memory 312 and the second controller 320 may also comprise a processor 321 and a memory 322. The first controller 310 and the second controller 320 may be communicably connected with each other via an ethernet connection 330.

On occasions, the connection 330 may use a special protocol such as Automation Device Specification (ADS) Protocol provided by Beckhoff company.

And the second control unit 320 may be communicably connected to the slaves and the connection may use Ethercat provided by Beckhoff company but it is not so limited.

FIG. 3(b) illustrates an example of a single control unit 350. This single control unit also may comprise a processor 351 and a memory 352.

The control unit 350 may be communicably connected to the slaves and the connection may use Ethercat provided by Beckhoff company but it is not limited.

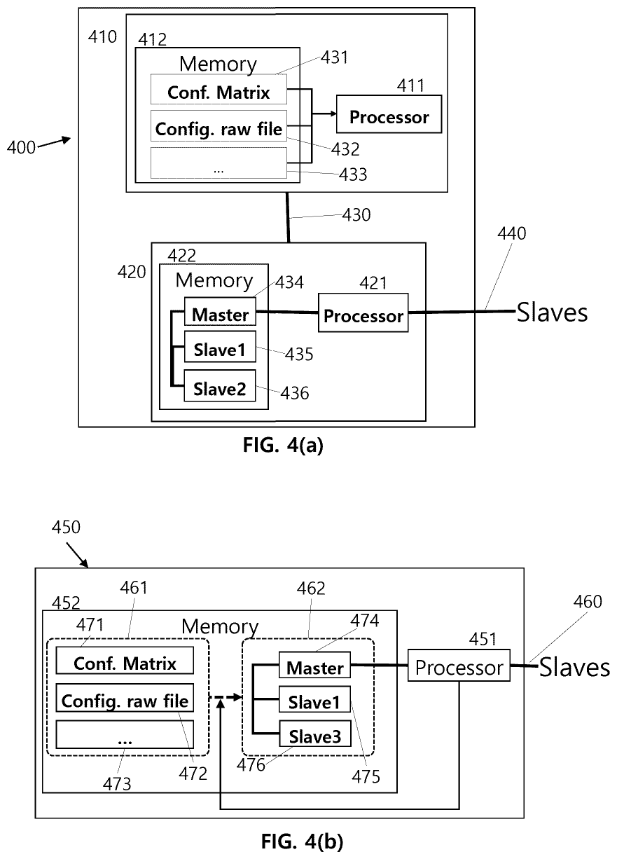

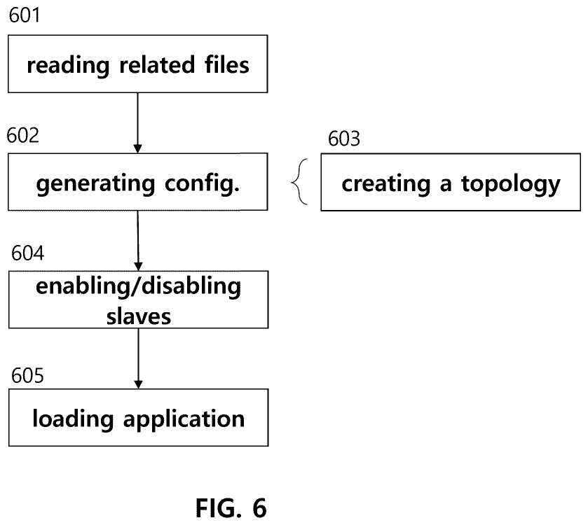

FIG. 4(a) illustrates an example of how configuration is done in the control unit 400's 2 independent control units 410, 420. The method of configuration would be explained with the figures in FIG. 4(a) and FIG. 6.

Firstly, the first control unit 410's processor 411 reads in from the memory 412 the configuration related files such as configuration matrix 431 and configuration raw file 432 in reading step (601). Additional files 433 could be also read in this step.

The processor 411 generates a configuration matrix in generating step (602). It needs to be noted that the read-in configuration matrix in reading step (601) is an empty configuration matrix 510 illustrated in FIG. 5 and the generated configuration matrix is a final configuration matrix 550 in FIG. 5.

The (finally) generated configuration files may be more than one as illustrated in FIG. 5 (540, 541/550). So at least one file for configuration may be generated in generating step (602).

While generating the configuration matrix in the generating step (602), the processor 411 may also create a topology of the generated configuration matrix in creating step (603). This created topology is sent to the second control unit 420 and the second processor 421 uses this topology information to create a topology of the generated configuration information in the second memory 422. In this example, only slave1 435 and slave2 436 are enabled under the current PM(Master) 434. This configured and created topology depicted in the memory 422 will be used to control the slaves with a connection 440. The connection 440 may be an EtherCat provided by Beckhoff company.

In this example, the topology shows slaves 1 & 2 are connected in the memory 422 and slaves 1 & 3 are connected in the memory 452 respectively. The topology indicates which slaves comprise the PM.

After generating (and creating), the second processor 421 may enable and disable the slaves according to the generated configuration matrix 550 (or configuration file 541) in enabling/disabling step (604). The second processor 421 reads the generated file and/or the created topology from the memory 422 and executes enablement or disablement of the slaves.

Finally, the second processor 421 may load applications for controlling the slaves and the process module itself in the loading step (605).

In this way, the configuration for PMs in a substrate processing apparatus may be done with a two control unit condition.

FIG. 4(b) illustrates an example of how a configuration is done in the control unit 450. The method of configuration would be explained with the figures in FIG. 4(b) and FIG. 6.

In this single control unit case, the control unit 450's processor 451 reads in from the memory 452 the configuration related files such as configuration matrix 471 and configuration raw file 472 in a reading step (601). Additional files 473 could be also read in this step.

The processor 451 generates a configuration matrix in a generating step (602). The read-in configuration matrix in the reading step (601) may be an empty configuration matrix 510 illustrated in FIG. 5 and the generated configuration matrix may be a final configuration matrix 550 in FIG. 5.

While generating the configuration matrix in the generating step (602), the processor 451 may also create a topology of the generated configuration matrix in a creating step (603). The processor 451 uses this topology information to create a topology of the generated configuration information in the memory 452. In this example, slave1 475 and slave3 476 are enabled under the current PM(Master) 474. This configured and created topology depicted in the memory 452 will be used to control the slaves with a connection 440. The connection 440 may be an EtherCat provided by Beckhoff company.

After generating (and creating), the processor 451 may enable and disable the slaves according to the generated configuration matrix 550 (or configuration file 541) in an enabling/disabling step (604). The processor 451 reads the generated file and/or the created topology from the memory 452 and executes the enablement or disablement of the slaves.

Finally, the processor 451 may load applications for controlling the slaves and the process module itself in a loading step (605).

Just like the memory 422 in FIG. 4(a) or the memory 452 in FIG. 4(b), the slaves (or devices) are to be listed in memory and when real slave(device) need to be controlled, the corresponding slave in the memory is to be manipulated.

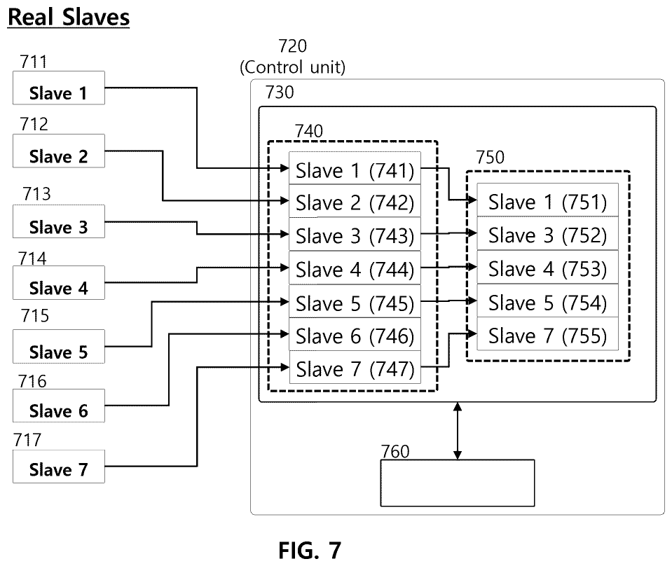

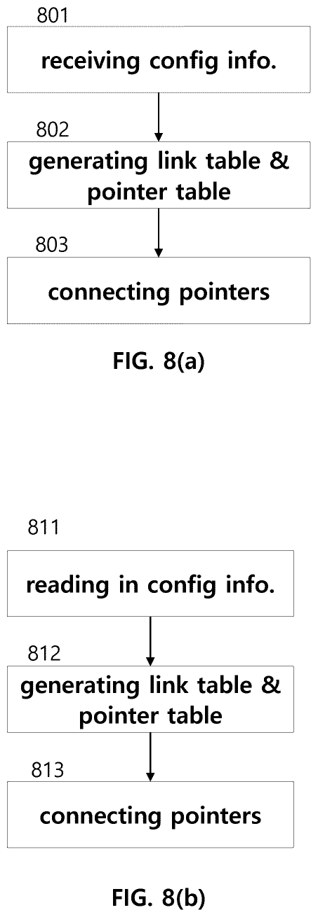

FIG. 7 illustrates an example of how a real slave(device) is connected to a memory table corresponding to it and how to Input/Output (I/O) configure it using tables and pointers linking between them.

A method of I/O configuration will be explained with FIG. 4(a) and FIG. 7.

The first processor 411 sends a configuration information (generated configuration related files explained above) to the second processor 421.

After receiving the configuration information in a receiving step (801), the second processor 421 starts to generate a pointer table 750 based on the received configuration information and the second processor 421 also starts to generate a link table 740 based on the slaves connected to the second control unit 420 in a generating step (802).

In some apparatuses, the link table 740 can be statically residing in the memory. If the link table 740 is embedded in the memory statically, only pointer table 750 may be generated in the generating step (802).

Since, the slaves are represented variables in the memory, the actual physical slaves could be controlled by reads and writes on the internal variables each corresponding to the physical slaves. Also, the pointer table 750 contains all the enabled slaves according to the received configuration information.

The processor 760 connects the enabled slave's variables in the link table 740 to the corresponding variables in the pointer table 750 in a connecting step (803).

In FIG. 7, slave 1 (711), slave 3 (713), slave 4 (714), slave 5 (715) and slave 7 (717) are enabled. And they are represented as variables in the link table 740, such as ‘slave 1’ (741), ‘slave 3’ (743), ‘slave 4’ (744), ‘slave 5’ (745) and ‘slave 7’ (747) and in the pointer table 750, such as ‘slave 1’ (751), ‘slave 3’ (752), ‘slave 4’ (753), ‘slave 5’ (754) and ‘slave 7’ (755).

In connecting step, ‘slave 1’ (741) in link table 740 is connected to ‘slave 1’ (751) in the pointer table 750 and ‘slave 3’ (743) in link table 740 is connected to ‘slave 3’ (752) in the pointer table 750, in FIG. 7 for example.

In this way, even though the specification of I/O is changed, by only changing the configuration information from the first processor, things that should be done from the specification change would be greatly decreased.

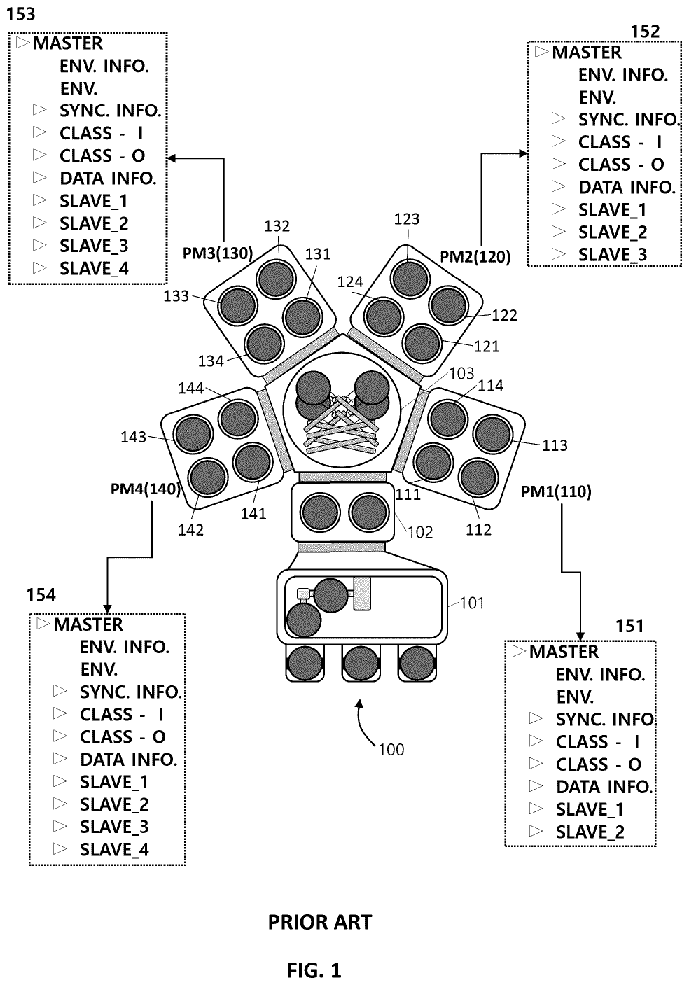

Above explanation is for 2 control unit situation like FIGS. 4(a) and 1 control unit situation like FIG. 4(b) is similar except that the configuration is read in from the memory 452 in a reading step (811). A generating step (812) and a connecting step (813) are almost similar except that the number of control unit (i.e. processor and memory also) is one, not two.

The slaves (or devices) in the present disclosure are not restricted to reaction chambers but may also comprise Radio Frequency (RF) generators, valves and wafer handling robots, or other components that could be used for processing substrates in the semiconductor field.

The above-described arrangements of apparatus are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A semiconductor processing apparatus, comprising:
a plurality of process modules, each of them configured to process wafers; and
each of the plurality of process modules comprises:
a plurality of slaves configured to receive and process wafers; and
a control unit comprising a processor and a memory, the control unit communicably connected to the plurality of slaves in series or in parallel and the control unit configured to configure and control the plurality of slaves;
wherein the processor is configured to read at least one configuration data file from the memory, generate at least one configuration file of the status of the plurality of slaves based on the at least one configuration data file, enable/disable the plurality of slaves according to the generated at least one configuration file, and load applications to control the plurality of slaves.

2. The apparatus according to claim 1, wherein one of the at least one configuration data file is configured to contain information of the status of the plurality of slaves.

3. The apparatus according to claim 1, wherein the processor is further configured to generate a topology of the plurality of slaves.

4. The apparatus according to claim 1, wherein the control unit further comprising a first control unit and a second control unit; and
wherein the second control unit communicably connected to the first control unit and communicably connected to the plurality of slaves in series or in parallel.

5. The apparatus according to claim 4, wherein the first control unit comprising a first processor and a first memory, and
wherein the first processor is configured to read at least one configuration data file from the first memory, generate at least one configuration file of the status of the plurality of slaves based on the at least one configuration data file, enable/disable the plurality of slaves according to the generated at least one configuration file, and load applications in the second processor to control the plurality of slaves.

6. A semiconductor processing apparatus, comprising:
a plurality of process modules, each of them configured to process wafers; and
each of the plurality of process modules comprising:
a plurality of slaves configured to receive and process wafers; and
a control unit comprising a processor and a memory, and the control unit communicably connected to the plurality of slaves in series or in parallel, the control unit configured to configure and control the plurality of slaves,
wherein the processor is configured to read configuration information from the memory, generate a pointer table according to the configuration information and a load table based on the plurality of slaves connected to the control unit in the memory, and connect pointers from the link table to the pointer table according to the configuration information.

7. The apparatus according to claim 6, wherein
the control unit comprising a first control unit and a second control unit; and
the second control unit communicably connected to the first control unit and communicably connected to the plurality of slaves in series or in parallel.

8. The apparatus according to claim 6, wherein
wherein the control unit further comprising a first control unit and a second control unit, and the second control unit comprising a second processor and a second memory.

9. The apparatus according to claim 8, wherein the second processor is configured to receive a configuration information from the first control unit, generate a pointer table according to the configuration information and a load table based on the plurality of slaves connected to the second control unit in the second memory, and connect pointers from the link table to the pointer table according to the configuration information.
